(19) United States
(12) Patent Application Publication
(10) Pub. No.: US 2025/0220918 A1
(43) Pub. Date: Jul. 3, 2025

(54) SEMICONDUCTOR DEVICE AND METHOD OF MANUFACTURING THE SAME

(71) Applicant: Renesas Electronics Corporation, Tokyo (JP)

(72) Inventor: Shibun TSUDA, Tokyo (JP)

(21) Appl. No.: 18/399,380

(22) Filed: Dec. 28, 2023

(51) Int. Cl. H10B 51/30; H01L 21/28; H01L 29/51

(52) U.S. Cl. CPC H10B 51/30; H10D 64/033; H10D 64/689

(57) ABSTRACT

A semiconductor device includes a ferroelectric memory cell, and the ferroelectric memory cell includes a select transistor and a memory transistor. A gate dielectric film of the select transistor includes a ferroelectric film, and a gate dielectric film of the memory transistor includes a ferroelectric film.

### BACKGROUND

The present disclosure relates to a semiconductor device and a method of manufacturing the same. The present disclosure relates to a technique applicable to, for example, a semiconductor device including a ferroelectric memory and a method of manufacturing the same.

In recent years, ferroelectric memory cells having ferroelectric films have been developed. In the ferroelectric memory cells, controlling the polarization direction of the ferroelectric film changes the state of the ferroelectric memory cell between the write state and the erase state. The ferroelectric memory cell can be driven at a lower voltage than a nonvolatile memory cell including a charge storage film such as a silicon nitride film.

There are disclosed techniques listed below. [Patent Document 1] Japanese Unexamined Patent Application Publication No. 2019-201172

Patent Document 1 discloses a ferroelectric memory cell formed on a semiconductor substrate. The ferroelectric memory cell includes a ferroelectric film. The ferroelectric film has grains that function as crystal nuclei.

### SUMMARY

A ferroelectric memory cell having a select transistor and a memory transistor is known. The select transistor selects a memory cell to be operated, and the memory transistor stores information. The select transistor is formed next to the memory transistor. In a manufacturing method of the ferroelectric memory cell, first, a dielectric film is formed on a semiconductor substrate. Next, a ferroelectric film is formed on the semiconductor substrate. The ferroelectric film is disposed next to the dielectric film. Next, a control gate electrode is formed on the dielectric film, and a memory gate electrode is formed on the ferroelectric film. Thereafter, the dielectric film and the ferroelectric film are processed using the control gate electrode and the memory gate electrode as masks to form a first gate dielectric film including the dielectric film and a second gate dielectric film including the ferroelectric film. Thereafter, through another manufacturing step, the select transistor having the first gate dielectric film and the control gate electrode is formed, and the memory transistor having the second gate dielectric film and the memory gate electrode is formed.

As described above, the dielectric film and the ferroelectric film are processed before the control gate electrode and the memory gate electrode are formed. The dielectric film and the ferroelectric film are processed using masks different from each other. Therefore, misalignment of the masks may cause formation defects of the dielectric film, the ferroelectric film, the control gate electrode, and the memory gate electrode. In order to prevent these formation defects, it is conceivable to secure a processing margin of the dielectric film, the ferroelectric film, the control gate electrode, and the memory gate electrode. That is, it is conceivable to increase the distances between the dielectric film, the ferroelectric film, the control gate electrode, and the memory gate electrode. However, in this case, the size of the ferroelectric memory cell increases, leading the size of the semiconductor chip to increase.

Other objects and novel features will become apparent from the description of this specification and the accompanying drawings.

In one embodiment of the present application, a semiconductor device includes a ferroelectric memory cell. The ferroelectric memory cell includes a control gate electrode, a memory gate electrode, a first gate dielectric film, a second gate dielectric film, a source region, and a drain region. The first gate dielectric film includes a ferroelectric film, and the second gate dielectric film includes a ferroelectric film.

In another embodiment of the present application, a manufacturing method of a semiconductor device includes forming a ferroelectric film on a semiconductor substrate, forming a control gate electrode and a memory gate electrode on the ferroelectric film, and processing the ferroelectric film to form a first gate dielectric film and a second gate dielectric film.

The techniques of the present application provide for miniaturization of a semiconductor device.

### BRIEF DESCRIPTION OF THE DRAWINGS

FIG. 1 is a cross-sectional view showing a semiconductor device according to a first embodiment.

FIG. 2 is a cross-sectional view showing a manufacturing step of the semiconductor device according to the first embodiment.

FIG. 3 is a cross-sectional view showing the manufacturing step of the semiconductor device following FIG. 2.

FIG. 4 is a cross-sectional view showing a manufacturing step of the semiconductor device following FIG. 3.

FIG. 5 is a cross-sectional view showing a manufacturing step of the semiconductor device following FIG. 4.

FIG. 6 is a cross-sectional view showing a manufacturing step of the semiconductor device following FIG. 5.

FIG. 7 is a cross-sectional view showing a manufacturing step of the semiconductor device following FIG. 6.

FIG. 8 is a cross-sectional view showing a manufacturing step of the semiconductor device following FIG. 7.

FIG. 9 is a table showing an example of the applied voltage to each portion during the operation of the ferroelectric memory cell.

FIG. 10 is a cross-sectional view showing a manufacturing step of a semiconductor device according to a comparative example.

FIG. 11 is a cross-sectional view showing a manufacturing step of the semiconductor device following FIG. 10.

FIG. 12 is a cross-sectional view showing a manufacturing step of the semiconductor device following FIG. 11.

FIG. 13 is a cross-sectional view showing a manufacturing step of the semiconductor device following FIG. 12.

FIG. 14 is a cross-sectional view showing a manufacturing step of the semiconductor device following FIG. 13.

FIG. 15 is a cross-sectional view showing the manufacturing step of semiconductor device following FIG. 14.

FIG. 16 is a cross-sectional view showing the manufacturing step of semiconductor device following FIG. 15.

FIG. 17 is a cross-sectional view showing a manufacturing step of the semiconductor device following FIG. 16.

FIG. 18 is an enlarged cross-sectional view of a portion of FIG. 15.

FIG. 19 is a cross-sectional view showing a semiconductor device according to a first modified example of the first embodiment.

FIG. 20 is a cross-sectional view showing a manufacturing step of the semiconductor device according to the first modified example of the first embodiment.

FIG. 21 is a cross-sectional view showing a manufacturing step of the semiconductor device following FIG. 20.

FIG. 22 is a cross-sectional view showing a semiconductor device according to a second embodiment.

FIG. 23 is a cross-sectional view showing a manufacturing step of the semiconductor device according to the second embodiment.

FIG. 24 is a cross-sectional view showing a manufacturing step of the semiconductor device following FIG. 23.

FIG. 25 is a cross-sectional view showing the manufacturing step of the semiconductor device following FIG. 24.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be less or greater than the specific number, except for cases where the number is specifically indicated and is clearly limited to the specific number in principle. Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary. In the drawings used in the embodiments, hatching may be omitted in order to make the drawings easier to see.

### First Embodiment

### Structure of Semiconductor Device

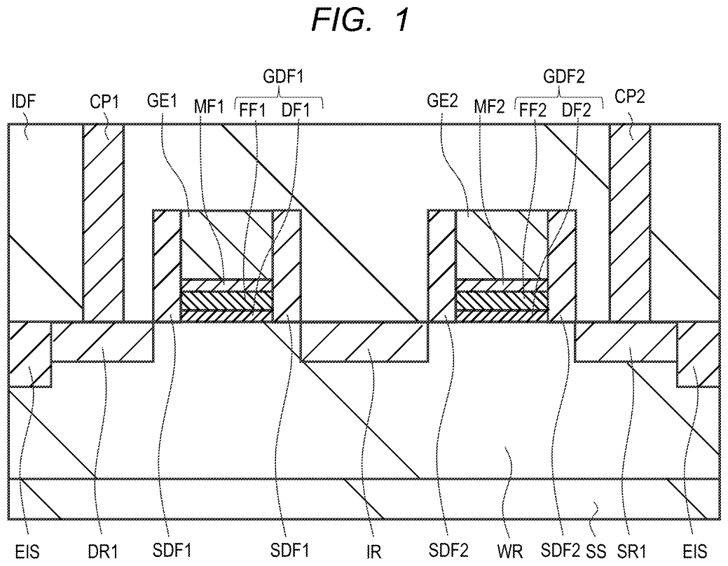

As shown in FIG. 1, a semiconductor device includes a semiconductor substrate SS, a well region WR, an element isolation structure EIS, a source region SR1, a drain region DR1, an impurity region IR, a gate dielectric film GDF1, a gate dielectric film GDF2, a metal film MF1, a metal film MF2, a gate electrode GE1, a gate electrode GE2, sidewall dielectric films SDF1, sidewall dielectric films SDF2, an interlayer dielectric film IDF, and contact plugs. The semiconductor device includes a ferroelectric memory cell, and the ferroelectric memory cell includes a select transistor and a memory transistor. The ferroelectric memory cell is formed on the semiconductor substrate SS, and includes at least the source region SR1, the drain region DR1, the gate dielectric film GDF1, the gate dielectric film GDF2, the metal film MF1, the metal film MF2, the gate electrode GE1, and the gate electrode GE2. The select transistor includes at least the source region SR1, the drain region DR1, the gate dielectric film GDF1, the metal film MF1, and the gate electrode GE1. The memory transistor includes at least the source region SR1, the drain region DR1, the gate dielectric film GDF2, the metal film MF2, and the gate electrode GE2. Other semiconducting elements other than the ferroelectric memory cells may also be formed on the semiconductor substrate SS.

The semiconductor substrate SS is made of, for example, p-type monocrystalline silicon (Si) having a resistivity of about 1 to 10 Ωcm. The semiconductor substrate SS has an upper surface and a lower surface. The semiconductor substrate SS includes the well region WR and element isolation structure EIS. The well region WR is formed in the semiconductor substrate SS. The conductivity type of the well region WR is, for example, p-type. The well region WR has a predetermined impurity concentration. The element isolation structure EIS is formed in the semiconductor substrate SS. The element isolation structure EIS is disposed at the upper surface of the semiconductor substrate SS. Specifically, the element isolation structure EIS is formed in the well region WR to surround an upper portion of the well region WR. The element isolation structure EIS includes a trench and a dielectric film embedded in the trench. The element isolation structure EIS has a function of electrically isolating the semiconductor devices adjacent to each other.

The source region SR1 is formed in the semiconductor substrate SS and in the well region WR, and is disposed at the upper surface of the semiconductor substrate SS. The depth of the source region SR1 is less than the depth of the well region WR. The impurity concentration of the source region SR1 is greater than the impurity concentration of the well region WR. The conductivity type of the source region SR1 is, for example, n-type. The source region SR1 may have an LDD structure. The source region SR1 includes, for example, arsenic or phosphorus. The drain region DR1 is formed in the semiconductor substrate SS and in the well region WR, and is disposed at the upper surface of the semiconductor substrate SS. The depth of the drain region DR1 is less than the depth of the well region WR. The impurity concentration of the drain region DR1 is greater than the impurity concentration of the well region WR. The drain region DR1 may have an LDD structure. The drain region DR1 is spaced apart from the source region SR1. The drain region DR1 and the source region SR1 are surrounded by the element isolation structure EIS in plan view. Silicide layers may be formed on the drain region DR1 and the source region SR1.

The impurity region IR is formed in the semiconductor substrate SS and in the well region WR, and is disposed at the upper surface of the semiconductor substrate SS. The depth of the impurity region IR is less than the depth of the well region WR. The conductivity type of the impurity region IR is, for example, n-type. The impurity concentration of the impurity region IR is greater than the impurity concentration of the well region WR. The impurity region IR is disposed between the drain region DR1 and the source region SR1 in cross-sectional view. The impurity region IR is disposed so as not to be connected to the wiring or the plug, and is in an electrically floating state. The impurity region IR is formed to connect the channel of the select transistor and the channel of the memory transistor.

The gate dielectric film GDF1 is formed on the semiconductor substrate SS, the metal film MF1 is formed on the gate dielectric film GDF1, and the gate electrode GE1 is formed on the metal film MF1. Specifically, the gate dielectric film GDF1 is formed on a portion of the semiconductor substrate SS located between the drain region DR1 and the impurity region IR in cross-sectional view. The gate dielectric film GDF1 includes the dielectric film DF1 and the ferroelectric film FF1. The dielectric film DF1 is formed on the semiconductor substrate SS, and the ferroelectric film FF1 is formed on the dielectric film DF1 so that the dielectric film DF1 is disposed between the semiconductor substrate SS and the ferroelectric film FF1. The dielectric film DF1 is formed of a paraelectric film, and is formed of, for example, a silicon oxide film. In a direction perpendicular to the upper surface of the semiconductor substrate SS, the thickness of the dielectric film DF1 is, for example, 1 nm or more and 3 nm or less. The ferroelectric film FF1 disposed between the dielectric film DF1 and the gate electrode GE1 is formed of, for example, a metal oxide film, and is formed of a high dielectric constant film having a dielectric constant higher than that of the silicon nitride film. The ferroelectric film FF1 includes, for example, hafnium, oxygen, and zirconium. The ferroelectric film FF1 may include at least one of silicon, germanium, yttrium, lanthanum, and ytterbium instead of zirconium. In the direction perpendicular to the upper surface of the semiconductor substrate SS, the thickness of the ferroelectric film FF1 is, for example, 6 nm or more and 20 nm or less.

The metal film MF1 formed on the gate dielectric film GDF1 is disposed between the ferroelectric film FF1 and the gate electrode GE1. The metal film MF1 is formed of, for example, a titanium nitride film, a tantalum nitride film, or a tungsten film. In the direction perpendicular to the upper surface of the semiconductor substrate SS, the thickness of the metal film MF1 is, for example, 2 nm or more and 20 nm or less. The metal film MF1 is used to efficiently crystallize the ferroelectric film FF1. Therefore, the metal film MF1 may not be formed as long as the ferroelectric film FF1 can be efficiently crystallized without forming the metal film MF1. The metal film MF1 and the gate electrode GE1 function as the control gate electrode of the select transistor.

The gate electrode GE1 is formed on the gate dielectric film GDF1. Specifically, when the metal film MF1 is formed on the gate dielectric film GDF1, the gate electrode GE1 is formed on the metal film MF1. The gate electrode GE1 is formed of, for example, a polycrystalline silicon film into which an n-type impurity is introduced. The gate electrode GE1 may be formed of a titanium nitride film, an aluminum film, or a tungsten film. In addition, the gate electrode GE1 may be formed of a stacked film including two or more conductive films.

The sidewall dielectric films SDF1 are formed on the semiconductor substrate SS and the side surfaces of the gate electrode GE1. The sidewall dielectric films SDF1 are formed of, for example, a stacked film including a silicon oxide film and a silicon nitride film.

The gate dielectric film GDF2 is formed on the semiconductor substrate SS, the metal film MF2 is formed on the gate dielectric film GDF2, and the gate electrode GE2 is formed on the metal film MF2. Specifically, the gate dielectric film GDF2 is formed on a portion of the semiconductor substrate SS located between the source region SR1 and the impurity region IR in cross-sectional view. The gate dielectric film GDF2 includes the dielectric film DF2 and the ferroelectric film FF2. The dielectric film DF2 is formed on the semiconductor substrate SS, and the ferroelectric film FF2 is formed on the dielectric film DF2 so that the dielectric film DF2 is disposed between the semiconductor substrate SS and the ferroelectric film FF2. The dielectric film DF2 is formed of a paraelectric film, and is formed of, for example, a silicon oxide film. In the direction perpendicular to the upper surface of the semiconductor substrate SS, the thickness of the dielectric film DF2 is, for example, 1 nm or more and 3 nm or less. The ferroelectric film FF2 disposed between the dielectric film DF2 and the gate electrode GE2 is formed of, for example, a metal oxide film, and is formed of a high dielectric constant film having a dielectric constant higher than that of the silicon nitride film. The ferroelectric film FF2 includes, for example, hafnium, oxygen, and zirconium. The ferroelectric film FF2 may include at least one of silicon, germanium, yttrium, lanthanum, and ytterbium instead of zirconium. In the direction perpendicular to the upper surface of the semiconductor substrate SS, the thickness of the ferroelectric film FF2 is, for example, 6 nm or more and 20 nm or less. The thickness of the ferroelectric film FF2 is the same as the thickness of the ferroelectric film FF1.

The metal film MF2 formed on the gate dielectric film GDF2 is disposed between the ferroelectric film FF2 and the gate electrode GE2. The metal film MF2 is formed of, for example, a titanium nitride film, a tantalum nitride film, or a tungsten film. In the direction perpendicular to the upper surface of the semiconductor substrate SS, the thickness of the metal film MF2 is, for example, 2 nm or more and 20 nm or less. The metal film MF2 is used to efficiently crystallize the ferroelectric film FF2. Therefore, the metal film MF2 may not be formed as long as the ferroelectric film FF2 can be efficiently crystallized without forming the metal film MF2. The metal film MF2 and the gate electrode GE2 function as the memory gate electrode of the memory transistor.

The gate electrode GE2 is formed on the gate dielectric film GDF2. Specifically, when the metal film MF2 is formed on the gate dielectric film GDF2, the gate electrode GE2 is formed on the metal film MF2. The gate electrode GE2 is formed of, for example, a polycrystalline silicon film into which an n-type impurity is introduced. The gate electrode GE2 may be formed of a titanium nitride film, an aluminum film, or a tungsten film. In addition, the gate electrode GE2 may be formed of a stacked film including two or more conductive films.

The sidewall dielectric films SDF2 are formed on the semiconductor substrate SS and the side surfaces of the gate electrode GE2. The sidewall dielectric films SDF2 are formed of, for example, a stacked film including a silicon oxide film and a silicon nitride film.

The interlayer dielectric film IDF is formed on the semiconductor substrate SS. Specifically, the interlayer dielectric film IDF is formed on the semiconductor substrate SS so as to cover the ferroelectric memory cell. The interlayer dielectric film IDF is formed of, for example, a silicon oxide film. The contact plugs are formed in the interlayer dielectric film IDF. Each of the contact plugs is formed of a barrier metal film and a conductive film. The barrier metal film is formed of a titanium film, a titanium nitride film, or a laminated film thereof, and the conductive film is formed of a tungsten film. The contact plugs include the contact plug CP1 and the contact plug CP2. The contact plug CP1 is connected to the drain region DR1, and the contact plug CP2 is connected to the source region SR1. Although not shown, the semiconductor device includes a contact plug disposed on the gate electrode GE1 and a contact plug disposed on the gate electrode GE2.

Although not shown, a multilayer wiring layer is disposed on the interlayer dielectric film. The multilayer wiring layer includes wirings and interlayer dielectric films, and each of the wirings is connected to each of the contact plugs.

### Manufacturing Method of Semiconductor Device

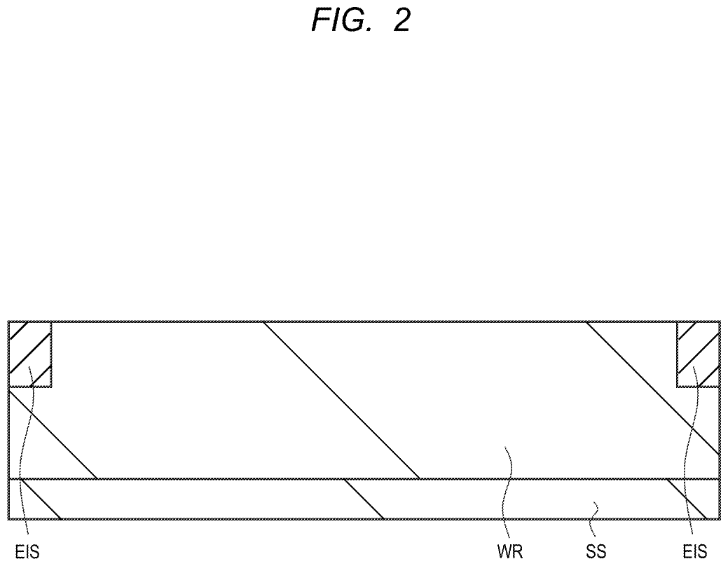

As shown in FIG. 2, the semiconductor substrate SS is prepared. Next, a trench is formed in the semiconductor substrate SS by a photolithography technique and an etching process. Next, a dielectric film is formed on the semiconductor substrate SS so as to be embedded in the trench. Thereafter, the dielectric film formed outside the trench is removed by using CMP (Chemical Mechanical Polishing) method to form the element isolation structure EIS. Next, the well region WR is formed in the semiconductor substrate SS by introducing impurities into the semiconductor substrate SS using a photolithography technique and an ion-implantation method.

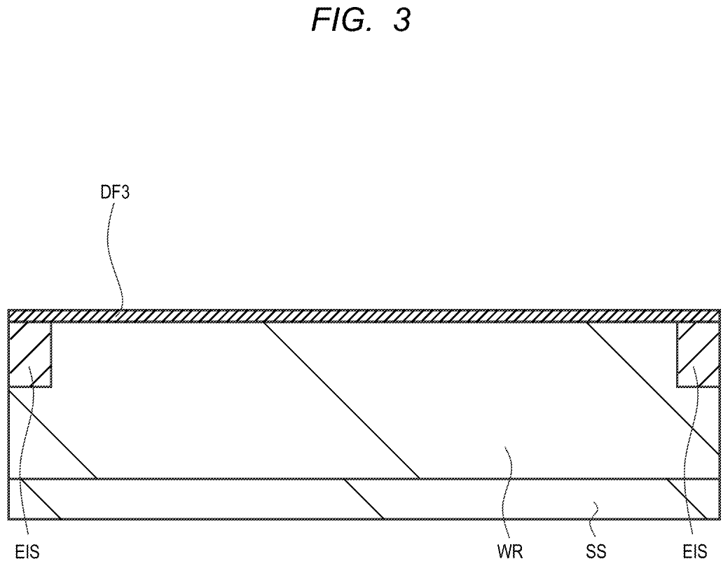

Next, as shown in FIG. 3, a heat treatment is performed on the upper surface of the semiconductor substrate SS to form a dielectric film DF3. The heat treatment for forming the dielectric film DF3 is performed in an oxygen-containing atmosphere. In the direction perpendicular to the upper surface of the semiconductor substrate SS, the thickness of the dielectric film DF3 is, for example, 1 nm or more and 3 nm or less.

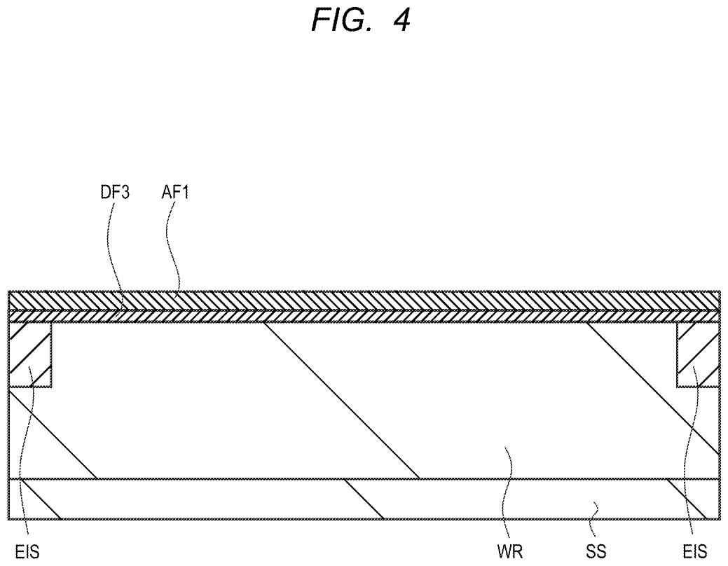

Next, as shown in FIG. 4, an amorphous film AF1 is formed on the dielectric film DF3 by, for example, an ALD (Atomic Layer Deposition) method. In the direction perpendicular to the upper surface of the semiconductor substrate SS, the thickness of the amorphous film AF1 is, for example, 6 nm or more and 20 nm. The amorphous film AF1 includes, for example, hafnium, oxygen, and zirconium. The amorphous film AF1 may include at least one of silicon, germanium, yttrium, lanthanum, and ytterbium instead of zirconium.

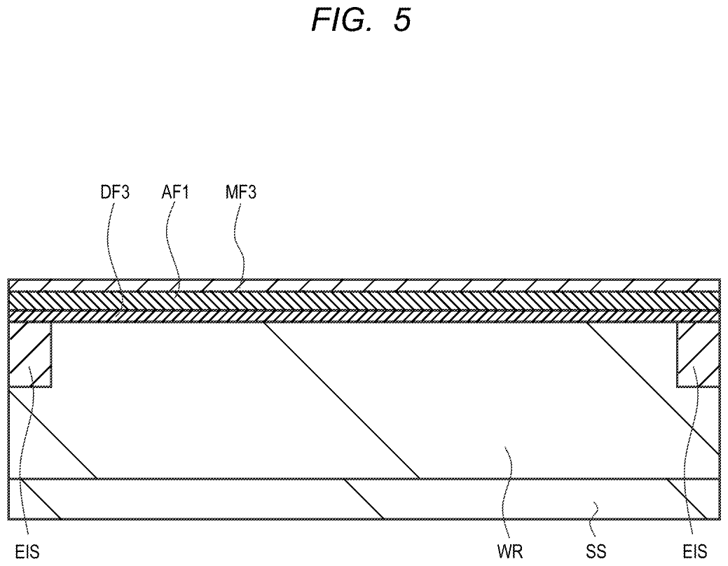

Next, as shown in FIG. 5, a metal film MF3 is formed on the amorphous film AF1 by, for example, a CVD method or a sputtering method. The metal film MF3 is formed of, for example, a titanium nitride film, a tantalum nitride film, or a tungsten film. In the direction perpendicular to the upper surface of the semiconductor substrate SS, the thickness of the metal film MF3 is, for example, 2 nm or more and 20 nm or less. The metal film MF3 is formed to apply stresses onto the amorphous film AF1.

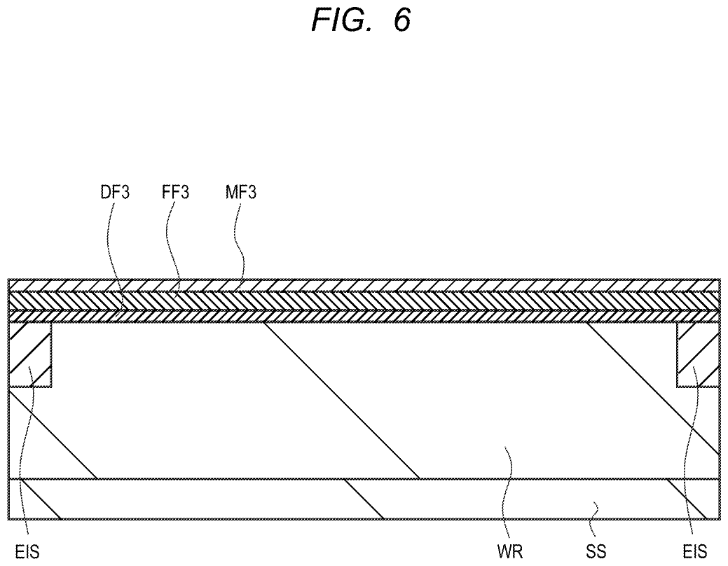

Next, as shown in FIG. 6, a heat treatment is performed on the amorphous film AF1 to crystallize the amorphous film AF1, thereby forming a ferroelectric film FF3 on the semiconductor substrate SS. The heat treatment for crystallizing the amorphous film AF1 is performed in a state where the metal film MF3 is formed on the amorphous film AF1. The heat treatment for crystallizing the amorphous film AF1 is performed by, for example, an RTA (Rapid Thermal Annealing) method or an annealing method using microwaves. Stresses from the metal film MF3 control the orientation of the crystals in the ferroelectric film FF3. When the amorphous film AF1 is crystallized to the ferroelectric film FF3, the metal film MF3 has a function of orienting the crystalline phase of the ferroelectric film FF3 into a rectangular crystal.

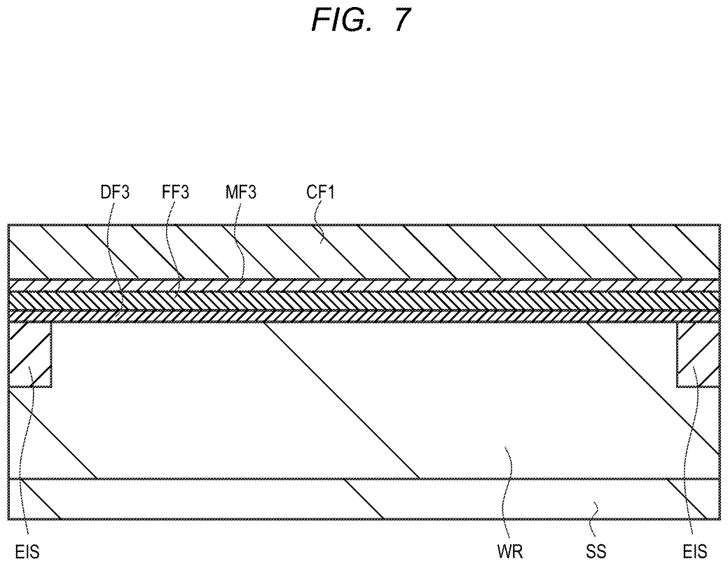

Next, as shown in FIG. 7, a conductive film CF1 is formed on the metal film MF3 by, for example, a CVD method. The conductive film CF1 is formed of, for example, polycrystalline silicon into which an n-type impurity is introduced. When the metal film MF3 is not formed on the ferroelectric film FF3, the conductive film CF1 is formed on the ferroelectric film FF3.

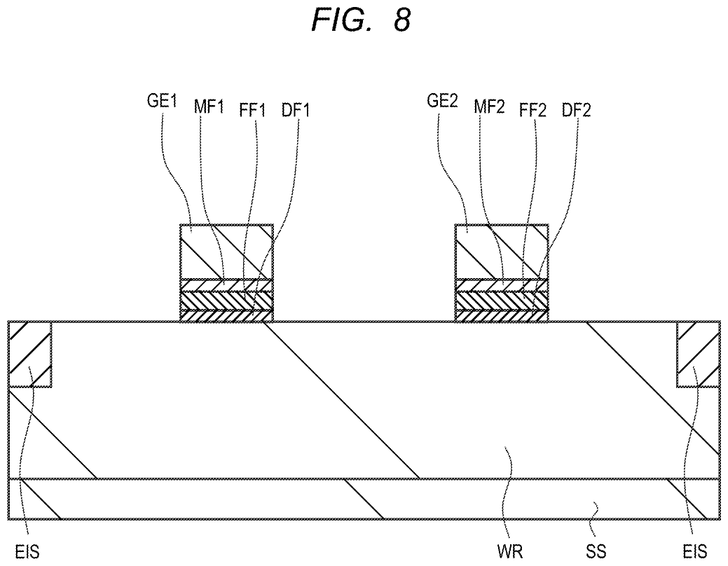

Next, as shown in FIG. 8, the gate electrode GE1, the gate electrode GE2, the gate dielectric film GDF1, and the gate dielectric film GDF2 are formed. First, a mask film is formed on the conductive film CF1 by known methods. Next, the conductive film CF1 is processed by an anisotropic etching method using the mask film to form the gate electrode GE1 and the gate electrode GE2. Next, the metal film MF3, the ferroelectric film FF3, and the dielectric film DF3 are processed using the gate electrode GE1 and the gate electrode GE2 as masks to form the metal film MF1, the metal film MF2, the ferroelectric film FF1, the ferroelectric film FF2, the dielectric film DF1, and the dielectric film DF2.

Next, the drain region DR1, the source region SR1, the impurity region IR, the sidewall dielectric films SDF1, the sidewall dielectric films SDF2, the interlayer dielectric film IDF, and the contact plugs are formed by known methods. Thus, the semiconductor device having the structure shown in FIG. 1 is formed.

### Operation of Semiconductor Device

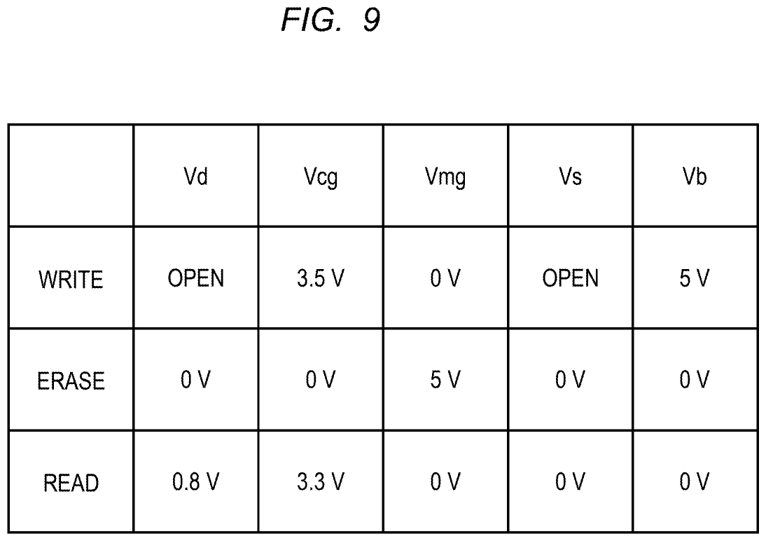

Specifically, FIG. 9 shows an example of the voltage applied to each portion in the write operation, the erase operation, and the read operation. Each voltage shown in FIG. 9 is applied to a selected memory cell that is an operation target, and is not applied to a non-selected memory cell that is not an operation target. A voltage different from the voltage shown in FIG. 9 is applied to the non-selected memory cell. FIG. 9 shows a voltage Vd applied to the drain region DR1 of the ferroelectric memory cell, a voltage Vcg applied to the gate electrode GE1, a voltage Vmg applied to the gate electrode GE2, a voltage Vs applied to the source region SR1, and a voltage Vb applied to the well region WR during each of a write operation, an erase operation, and a read operation. Note that the applied voltages shown in FIG. 9 are an example.

In the first embodiment, a state in which the ferroelectric film FF2 is polarized upward and the threshold voltage of the memory transistor is relatively high is defined as a write state. Further, a state in which the ferroelectric film FF2 is polarized downward and the threshold voltage of the memory transistor is relatively low is defined as an erase state.

In the write operation, for example, the voltages shown in the “write” row of FIG. 9 are applied to each portion of the selected memory cell to be written. As a result, the ferroelectric film FF2 is polarized upward, the threshold voltage of the memory transistor is increased, and the ferroelectric film FF2 becomes a write state. Even if the voltages shown in the “write” row of FIG. 9 are no longer applied, the polarization in the ferroelectric film FF2 remains until the erase operation is performed on the selected memory cell.

In the erase operation, for example, the voltages shown in the row of “erase” in FIG. 9 are applied to each portion of the selected memory cell to be erased. As a result, the ferroelectric film FF2 is polarized downward, the threshold voltage of the memory transistor is lowered, and the ferroelectric film FF2 becomes an erase state. Even if the voltages shown in the “erase” row of FIG. 9 are no longer applied, the polarization in the ferroelectric film FF2 remains until the write operation is performed on the selected memory cell.

In a read operation, for example, the voltages shown in a row of “read” in FIG. 9 are applied to each portion of the selected memory cell to be read. The voltage Vmg applied to the gate electrode GE2 is set to a value between the threshold voltage of the memory transistor in the write state and the threshold voltage of the memory transistor in the erase state. Therefore, the magnitude of the current flowing through the memory transistor in the write state is different from the magnitude of the current flowing through the memory transistor in the erase state. The state of the ferroelectric memory cell can be determined by detecting the magnitude of the current flowing through the ferroelectric memory cell in the read operation.

The select transistor selects the memory transistor to be operated. If the threshold voltage of the select transistor varies, the performance of the ferroelectric memory cell varies. For example, the select transistor may not select the memory transistor to be operated. Therefore, it is preferable that the threshold voltage of the select transistor is less likely to vary. In the first embodiment, the select transistor includes the ferroelectric film FF1, and the select transistor may operate as a memory cell. In such case, the write operation or the erase operation is performed on the select transistor, and the threshold voltage of the select transistor may vary. In order to suppress variations in the threshold voltage of the select transistor, the write operation may be performed on the select transistor after forming the select transistor. For example, in the write operation, the voltage of 5 V is applied to the gate electrode GE1, and the voltage of 0 V is applied to each of the drain region DR1, the source region SR1, and the well region WR. Then, the select transistor becomes in the erase state, and the select transistor has a relatively low threshold voltage. For example, the threshold voltage of the select transistor is set to be lower than the positive voltage applied to the gate electrode GE1 in the operation of the select transistor. Therefore, the positive voltage applied to the gate electrode GE1 in the operation of the select transistor can be prevented from varying the threshold voltage of the select transistor.

### Main Features and Effects of First Embodiment

The main features and effects of the manufacturing method of the semiconductor device and the structure of the semiconductor device according to the first embodiment will be described in comparison with the manufacturing method of the semiconductor device according to a comparative example.

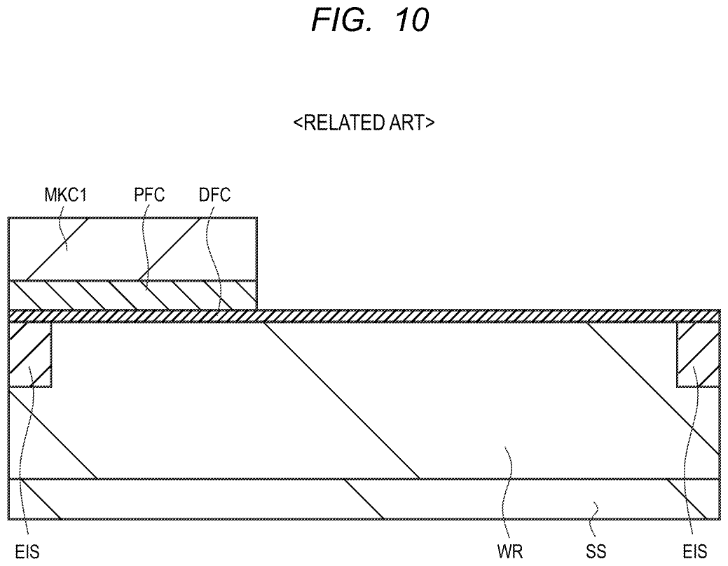

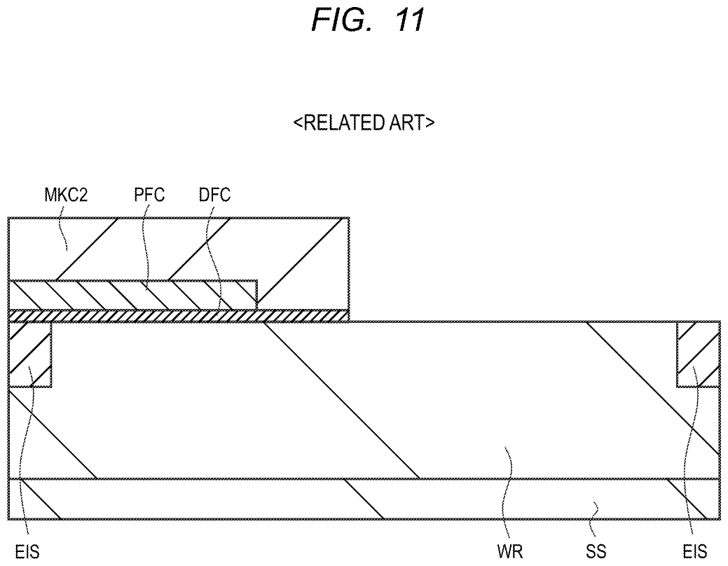

In the manufacturing method of the semiconductor device according to the comparative example, similar to the first embodiment, the semiconductor substrate SS is prepared and the well region WR and the element isolation structure EIS are formed in the semiconductor substrate SS referring back to FIG. 2. Next, in a comparative example, as shown in FIG. 10, a dielectric film DFC and a protective film PFC are formed on the semiconductor substrate SS. First, the dielectric film DFC is formed on the semiconductor substrate SS by performing a heat treatment on the semiconductor substrate SS, for example. Next, the protective film PFC is formed on the dielectric film DFC by, for example, a CVD method. Thereafter, a mask film MKC1 is formed on the protective film PFC by a CVD method or a photolithography technique. Thereafter, the protective film PFC is processed by an etching process to remove the protective film PFC exposed from the mask film MKC1. The processed protective film PFC covers at least a portion of the upper surface of the semiconductor substrate SS where the gate dielectric film GDFC1 is to be formed and exposes a portion of the upper surface of the semiconductor substrate SS where the gate dielectric film GDFC2 is to be formed. Next, as shown in FIG. 11, a mask film MKC2 is formed on the protective film PFC and the dielectric film DFC by a CVD method or a photolithography technique. The mask film MKC2 is formed on the dielectric film DFC so as to cover the protective film PFC. Thereafter, the dielectric film DFC is processed by an etching process to remove the dielectric film DFC exposed from the mask film MKC2. Thus, the upper surface of the semiconductor substrate SS where the gate dielectric film GDFC2 is to be formed is exposed. Thereafter, although not shown, a dielectric film is formed next to the processed dielectric film DFC and on the upper surface of the semiconductor substrate SS.

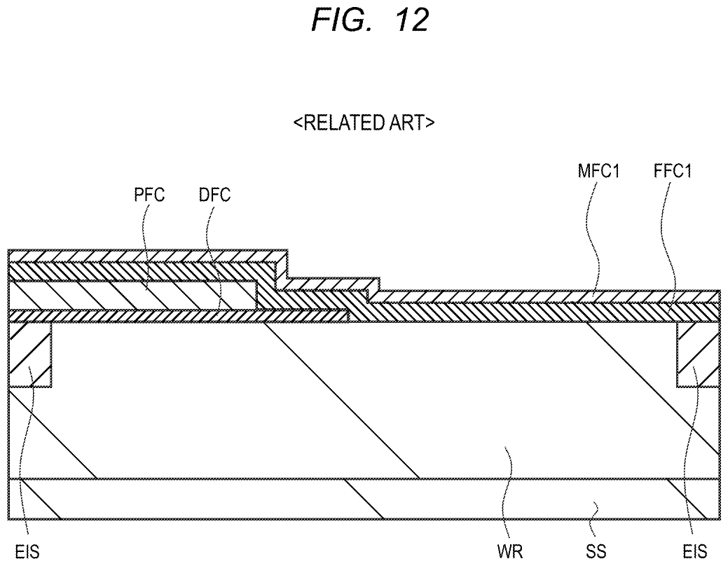

Next, as shown in FIG. 12, a ferroelectric film FFC1 and a metal film MFC1 are formed on the semiconductor substrate SS. First, an amorphous film is formed on the semiconductor substrate SS by, for example, an ALD method. The amorphous film is formed so as to cover the dielectric film DFC and the protective film PFC. Next, the metal film MFC1 is formed on the amorphous film by, for example, a CVD method or a sputtering method. The metal film MFC1 is formed so as to cover the dielectric film DFC and the protective film PFC. Next, the ferroelectric film FFC1 is formed by performing a heat treatment on the amorphous film to crystallize the amorphous film.

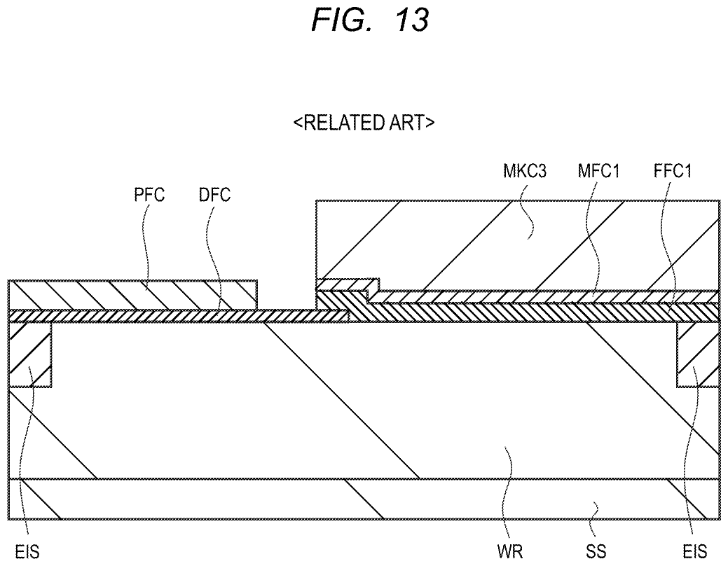

Next, as shown in FIG. 13, the metal film MFC1 and the ferroelectric film FFC1 are processed. First, the mask film MKC3 is formed on the metal film MFC1. Next, the metal film MFC1 and the ferroelectric film FFC1 are processed by an etching process to remove the metal film MFC1 and the ferroelectric film FFC1 exposed from the mask film MKC3. Thus, the side surface of the processed metal film MFC1 and the side surface of the processed ferroelectric film FFC1 are located on the dielectric film DFC, but not on the protective film PFC. That is, the side surface of the processed metal film MFC1 and the side surface of the processed ferroelectric film FFC1 are located on the dielectric film DFC exposed from the protective film PFC.

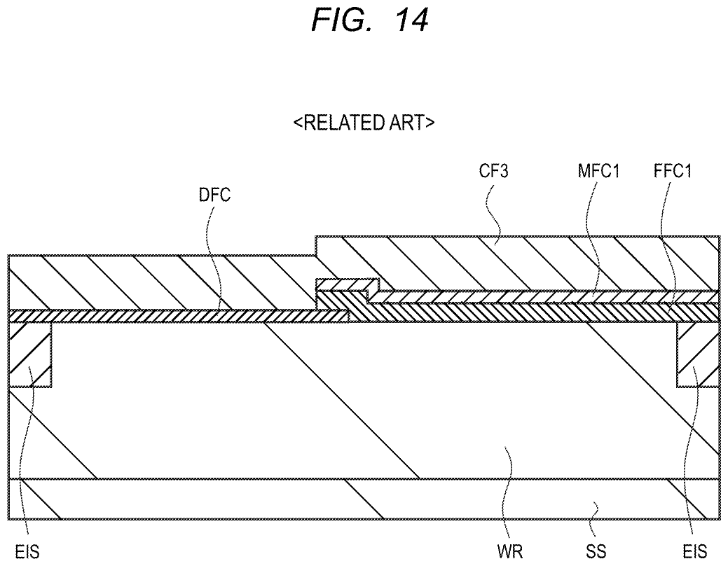

Next, as shown in FIG. 14, the protective film PFC is removed by an etching method. Next, a conductive film CF3 is formed on the semiconductor substrate SS. Specifically, the conductive film CF3 is formed on the dielectric film DFC and the metal film MFC1. When the metal film MFC1 is not formed on the ferroelectric film FFC1, the conductive film CF3 is formed on the ferroelectric film FFC1.

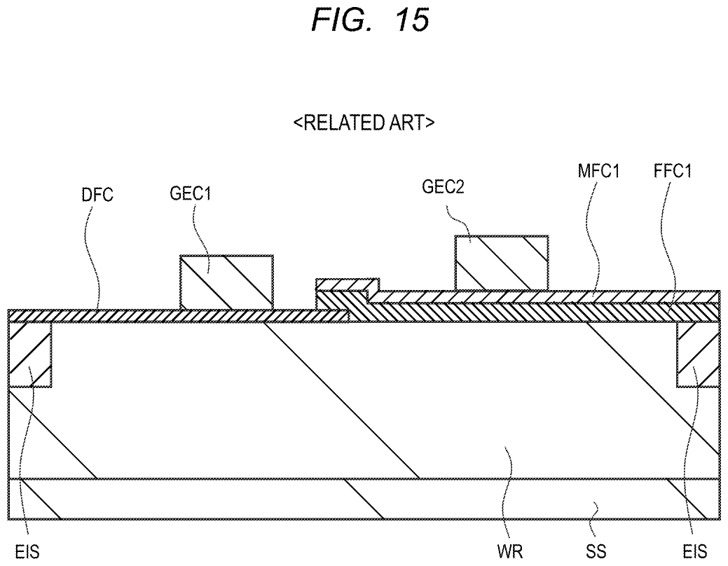

Next, as shown in FIG. 15, a mask film is formed on the conductive film CF3 by known methods. Next, the conductive film CF3 is processed by an etching process using the mask film. Thus, a gate electrode GEC1 and a gate electrode GEC2 are formed.

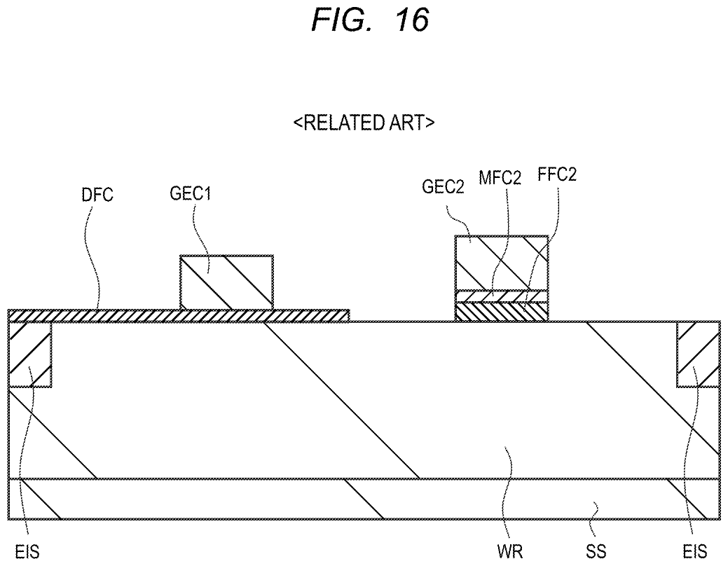

Next, as shown in FIG. 16, the metal film MFC1 and the ferroelectric film FFC1 are processed using the gate electrode GEC2 as a mask to form a metal film MFC2 and a ferroelectric film FFC2 under the gate electrode GEC2.

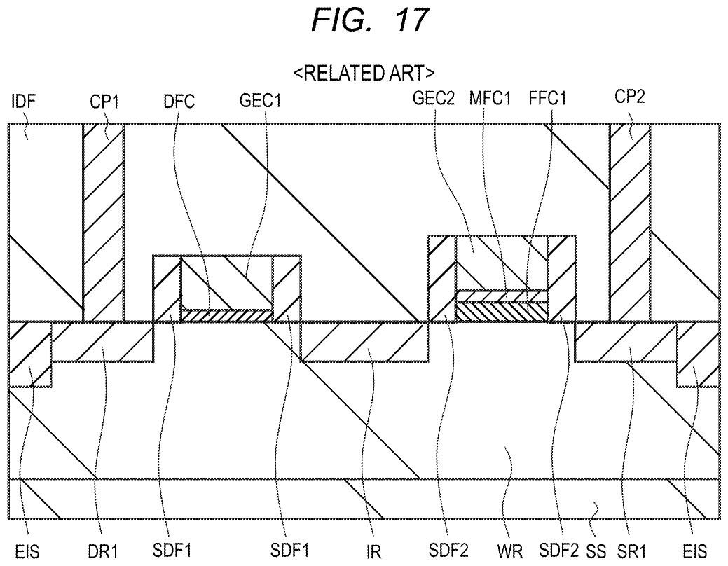

Next, as shown in FIG. 17, the drain region DR1, the source region SR1, the impurity region IR, the sidewall dielectric films SDF1, the sidewall dielectric films SDF2, the interlayer dielectric film IDF, the contact plug CP1, and the contact plug CP2 are formed by known methods. As described above, the semiconductor device according to the comparative example is manufactured.

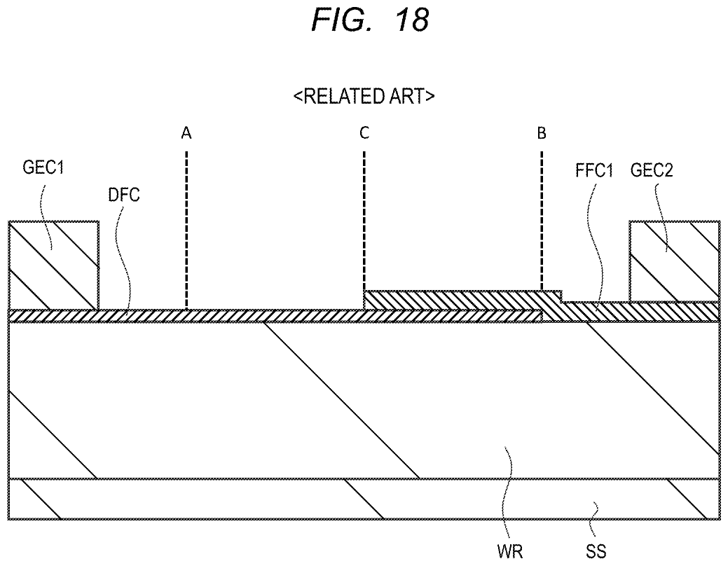

FIG. 18 shows a position where the mask film MKC1 is formed, a position where the mask film MKC2 is formed, and a position where the mask film MKC3 is formed. Specifically, in FIG. 18, a dotted line A indicates a position where an end portion of the mask film MKC1 for processing the protective film PFC shown in FIG. 10 is formed. A dotted line B indicates a position where an end portion of the mask film MKC2 for processing the dielectric film DFC shown in FIG. 11 is formed. A dotted line C indicates a position where an end portion of the mask film MKC3 for processing the ferroelectric film FFC1 shown in FIG. 13 is formed.

In the comparative example, the gate dielectric film GDFC2 of the memory transistor includes the ferroelectric film FFC2, while the gate dielectric film GDFC1 of the select transistor does not include the ferroelectric film. Therefore, referring back to FIG. 10 to FIG. 13, the manufacturing method of the semiconductor device according to the comparative example includes a step of processing the protective film PFC, a step of processing the dielectric film DFC, and a step of processing the ferroelectric film FFC1. Therefore, in order to manufacture the semiconductor device according to the comparative example, at least the mask film MKC1, the mask film MKC2, and the mask film MKC3 need to be formed. The mask film MKC1, the mask film MKC2, and the mask film MKC3 are formed by a CVD method, a photolithography technique, an etching process, or the like. Therefore, the manufacturing variation affects the formation position of the mask film MKC1, the formation position of the mask film MKC2, and the formation position of the mask film MKC3. The formation positions of the structures formed on the semiconductor substrate SS vary in the plane due to manufacturing variations.

For example, in the comparative example, the formation position of the mask film MKC1 may vary such that the distance between the mask film MKC1 and the mask film MKC3 decreases. Similarly, the formation position of the mask film MKC3 may vary such that the distance between the mask film MKC1 and the mask film MKC3 decreases. If the formation position of the mask film MKC1 varies such that the distance between the mask film MKC1 and the mask film MKC3 decreases, the end portion of the mask film MKC1 shown in FIG. 18 and the end portion of the mask film MKC3 shown in FIG. 18 may be interchanged with each other. In such case, for example, the formation defect may occur to the ferroelectric film FFC1 processed using the mask film MKC3. Therefore, the formation position of one mask film affects the formation position of another mask film, and there is a possibility that the protective film PFC, the dielectric film DFC, and the ferroelectric film FFC2 cannot be formed at a desired position. In order to form the protective film PFC, the dielectric film DFC, and the ferroelectric film FFC2 at a desired position, it is required to secure a sufficient distance between the formation position of one mask film and the formation position of another mask film. Further, in order to prevent the formation defect of the gate electrode GEC1, a sufficient distance must be ensured between the formation position of the end portion of the mask film MKC1 and the formation position of the gate electrode GEC1. In addition, in order to prevent the formation defect of the gate electrode GEC2, a sufficient distance must be secured between the formation position of the end portion of the mask film MKC2 and the formation position of the gate electrode GEC2.

As described above, when a sufficient distance is secured between the mask film MKC1, the mask film MKC2, the mask film MKC3, the gate electrode GEC1, and the gate electrode GEC2, the distance between the gate electrode GEC1 and the gate electrode GEC2 increases. Increasing the distance between the gate electrode GEC1 and the gate electrode GEC2 results in increasing the size of the ferroelectric memory cell. As a result, the size of the semiconductor chip on which the ferroelectric memory is mounted increases.

In the first embodiment, the gate dielectric film GDF1 includes the ferroelectric film FF1, and the gate dielectric film GDF2 includes the ferroelectric film FF2. Referring back to FIG. 8, in the first embodiment, the ferroelectric film FF3 is processed to form the ferroelectric film FF1 and the ferroelectric film FF2.

As shown in FIG. 8, the gate dielectric film GDF1 and the gate dielectric film GDF2 are formed by processing the metal film MF3, the ferroelectric film FF3, and the dielectric film DF3 using the gate electrode GE1 and the gate electrode GE2 as masks. Therefore, the first embodiment does not need to form the mask film MKC1 for processing the protective film PFC, the mask film MKC2 for processing the dielectric film DFC, and the mask film MKC3 for processing the ferroelectric film FFC1 as required in the comparative example. Therefore, the first embodiment does not need to secure a sufficient distance between the position where the mask film MKC1 is formed, the position where the mask film MKC2 is formed, and the position where the mask film MKC3 is formed. In the first embodiment, it is sufficient to secure a sufficient distance between the formation position of the gate electrode GE1 and the formation position of the gate electrode GE2. The distance between the gate electrode GE1 and the gate electrode GE2 in the first embodiment can be smaller than the distance between the gate electrode GEC1 and the gate electrode GEC2 in the comparative example. Therefore, compared with the semiconductor device according to the comparative example, the semiconductor device according to the first embodiment can be miniaturized.

In the first embodiment, not only the memory transistor includes the ferroelectric film FF2, but also the select transistor includes the ferroelectric film FF1. The ferroelectric film FF1 is formed of the high dielectric constant film. Even if the physical thickness of the dielectric film DFC in the comparative example and the physical thickness of the gate dielectric film GDF1 in the first embodiment are the same as each other, the equivalent oxide thickness of the gate dielectric film GDF1 can be reduced than the equivalent oxide thickness of the dielectric film DFC. Therefore, the performance of the semiconductor in the first embodiment can be improved while maintaining reliability of the semiconductor device in comparison with the semiconductor device in the comparative example.

### First Modified Example

### Structure of Semiconductor Device

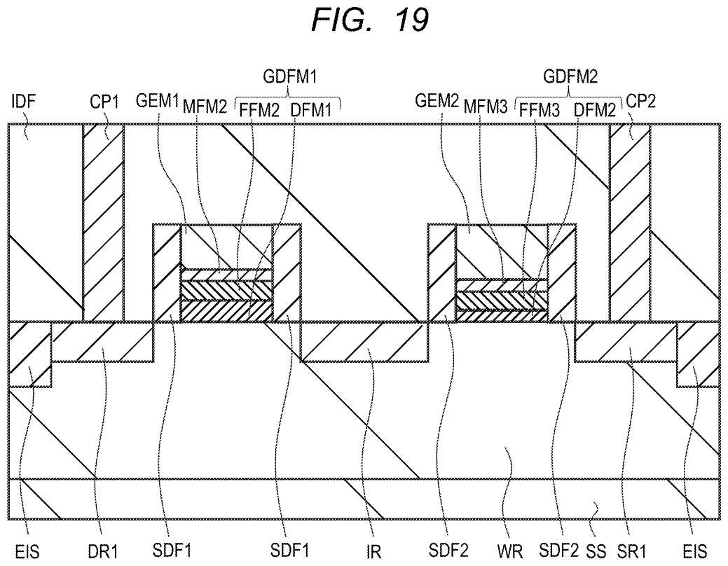

The first modified example is a modification of the first embodiment. As shown in FIG. 19, the semiconductor device according to the first modified example has the same configuration as the semiconductor device according to the first embodiment except for a thickness of the dielectric film DF1 and a thickness of the dielectric film DF2. In the first modified example, the thickness of the dielectric film DF1 is greater than the thickness of the dielectric film DF2. In a direction perpendicular to the upper surface of the semiconductor substrate SS, the thickness of the dielectric film DF1 is, for example, 4 nm or more and 8 nm or less. In a direction perpendicular to the upper surface of the semiconductor substrate SS, the thickness of the dielectric film DF2 is, for example, 1 nm or more and 3 nm or less.

### Manufacturing Method of Semiconductor Device

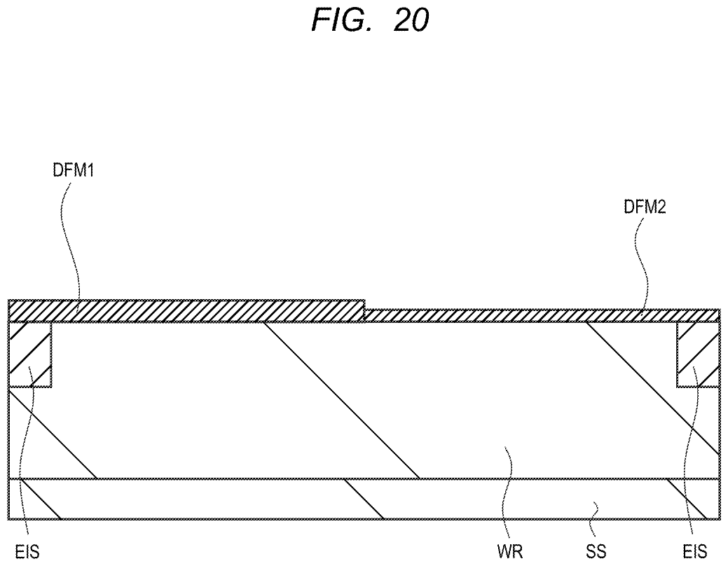

In the manufacturing method of the semiconductor device according to the first modified example, the semiconductor substrate SS is prepared and the well region WR and the element isolation structure EIS are formed in the semiconductor substrate SS as shown in FIG. 2. Next, as shown in FIG. 20, a dielectric film DFM1 is formed on the semiconductor substrate SS. The dielectric film DFM1 is formed by, for example, a thermal oxidation method or an ISSG oxidation method. Next, the dielectric film DFM1 is processed by a photolithography technique and an etching method to remove a portion of the dielectric film DFM1. As a result, the dielectric film DFM1 located on a portion of the upper surface of the semiconductor substrate SS where the gate dielectric film GDF2 is to be formed is removed, and the dielectric film DFM1 located on a portion of the upper surface of the semiconductor substrate SS where the gate dielectric film GDF1 is to be formed is not removed. Next, a dielectric film DFM2 is formed on the portion of the semiconductor substrate SS exposed from the dielectric film DFM1. The dielectric film DFM2 is formed by, for example, a thermal oxidation method or an ISSG oxidation method. A thickness of the dielectric film DFM1 is greater than a thickness of the dielectric film DFM2.

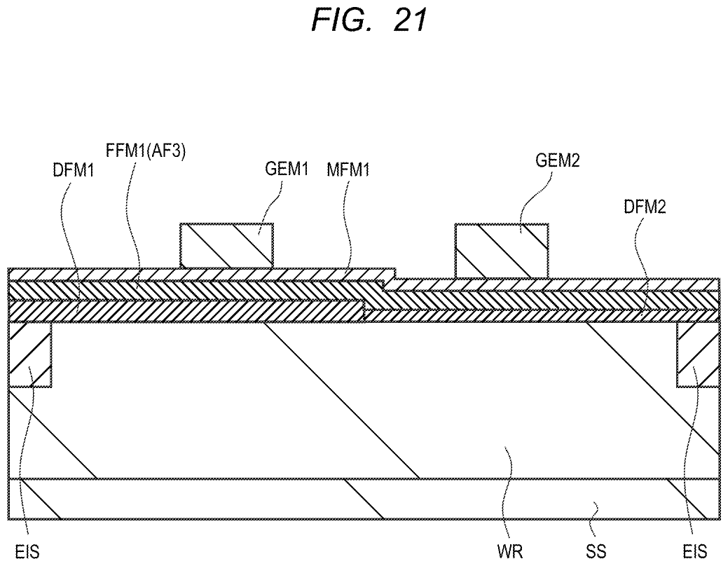

Next, as shown in FIG. 21, an amorphous film AF3 is formed on the dielectric film DFM1 and the dielectric film DFM2. The forming method and the configuration of the amorphous film AF3 in the first modified example are the same as the forming method and the configuration of the amorphous film AF1 in the first embodiment. Next, a metal film MFM1 is formed on the amorphous film AF3. The forming method and the configuration of the metal film MFM1 in the first modified example are the same as the forming method and the configuration of the metal film MF3 in the first embodiment. Next, the amorphous film AF3 is crystallized to form the ferroelectric film FFM1. The crystallization method of the amorphous film AF3 in the first modified example is the same as the crystallization method of the amorphous film AF1 in the first embodiment. Next, a gate electrode GEM1 and a gate electrode GEM2 are formed on the metal film MFM1. The forming method of the gate electrode GEM1 and the forming method of the gate electrode GEM2 in the first modified example are the same as the forming method of the gate electrode GE1 and the forming method of the gate electrode GE2 in the first embodiment.

Next, the metal film MFM1 and the ferroelectric film FFM1 are processed using the gate electrode GEM1 and the gate electrode GEM2 as masks. Thus, a metal film MFM2, a gate dielectric film GDFM1 including the ferroelectric film FFM2 and the dielectric film DFM1, a metal film MFM3, and a gate dielectric film GDFM2 including a ferroelectric film FFM3 and the dielectric film DFM2 shown in FIG. 19 are formed. Thereafter, the drain region DR1, the source region SR1, the impurity region IR, the sidewall dielectric films SDF1, the sidewall dielectric films SDF2, the interlayer dielectric film IDF, and the contact plugs are formed by known methods. Thus, the semiconductor device shown in FIG. 19 is manufactured.

### Main Features and Effects of First Modified Example

When the thickness of the dielectric film DF1 is insufficient, the performance of the select transistor may deteriorate. When the select transistor operates, a positive voltage is applied to the gate electrode GE1 of the select transistor. If the thickness of the dielectric film DF1 is not enough, electrons flowing through the semiconductor substrate SS are injected through the dielectric film DF1 to the interface between the dielectric film DF1 and the ferroelectric film FF1. Since electrons are present at the interface between the dielectric film DF1 and the ferroelectric film FF1, the strength of the electric field applied to the ferroelectric film FF1 increases, leading the select transistor to operate as a memory cell. In this case, the operation of the select transistor as a memory cell means that a write operation is performed on the select transistor. As a result, the threshold voltage of the select transistor rises, and there is a possibility that no current flows through the select transistor. As a result, the ferroelectric memory cell may not operate normally.

In the first modified example, the thickness of the dielectric film DFM1 is greater than the thickness of the dielectric film DFM2. Therefore, when the select transistor is operated, electrons flowing through the semiconductor substrate SS are less likely to be injected through the dielectric film DFM1 to the interface between the dielectric film DFM1 and the ferroelectric film FFM2. Therefore, the select transistor is less likely to operate as a memory cell, and the ferroelectric memory cell can operate normally. Also in the first modified example, as shown in FIG. 21, the ferroelectric film FFM1 is processed to form the ferroelectric film FFM2 and the ferroelectric film FFM3. Thus, the gate dielectric film GDFM1 including the ferroelectric film FFM2 is formed, and the gate dielectric film GDFM2 including the ferroelectric film FFM3 is formed. Therefore, similar to the first embodiment, the semiconductor device can be miniaturized.

### Second Embodiment

### Structure of Semiconductor Device

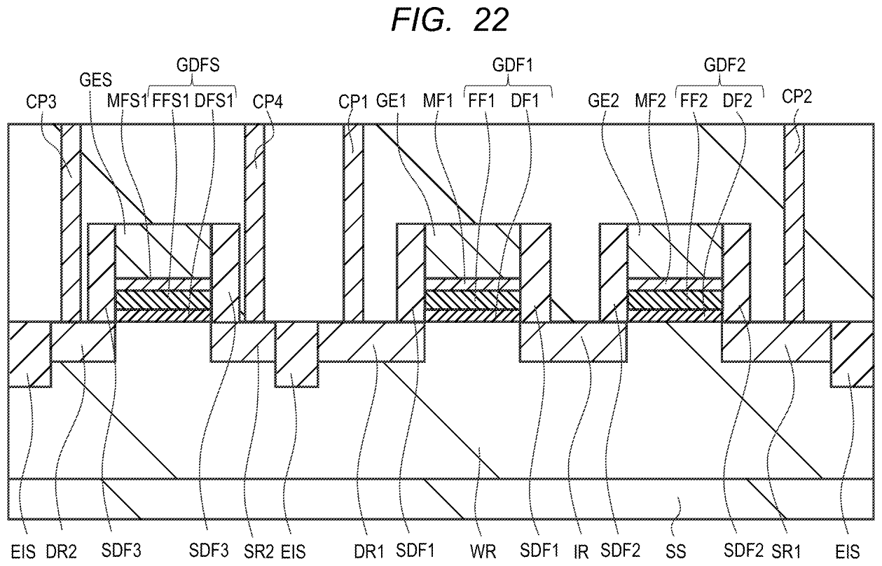

As shown in FIG. 22, the semiconductor device of the second embodiment includes a ferroelectric memory cell and a MISFET (Metal Insulator Semiconductor Field Effect Transistor). The ferroelectric memory cell and the MISFET may not be disposed adjacent to each other. Other semiconductor elements, dummy patterns, or the like may be disposed between the ferroelectric memory cell and the MISFET. The configuration of the ferroelectric memory cell according to the second embodiment is the same as the configuration of the ferroelectric memory cell according to the first embodiment. The MISFET includes at least a source region SR2, a drain region DR2, a gate dielectric film GDFS, a metal film MFS1, and a gate electrode GES.

The source region SR2 is formed in the semiconductor substrate SS and in the well region WR, and is disposed at the upper surface of the semiconductor substrate SS. The depth of the source region SR2 is less than the depth of the well region WR. The impurity concentration of the source region SR2 is greater than the impurity concentration of the well region WR. The conductivity type of the source region SR2 is, for example, n-type. The source region SR2 may have an LDD structure. The source region SR2 includes, for example, arsenic or phosphorus. The drain region DR2 is formed in the semiconductor substrate SS and in the well region WR, and is disposed at the upper surface of the semiconductor substrate SS. The depth of the drain region DR2 is less than the depth of the well region WR. The impurity concentration of the drain region DR2 is greater than the impurity concentration of the well region WR. The drain region DR2 may have an LDD structure. The drain region DR2 is spaced apart from the source region SR2. The drain region DR2 and the source region SR2 are surrounded by the element isolation structure EIS in plan view. Silicide layers may be formed on the drain region DR2 and the source region SR2.

The gate dielectric film GDFS is formed on the semiconductor substrate SS, a metal film MFS1 is formed on the gate dielectric film GDFS, and a gate electrode GES is formed on the metal film MFS1. Specifically, the gate dielectric film GDFS is formed on a portion of the semiconductor substrate SS located between the drain region DR2 and the source region SR2 in cross-sectional view. The gate dielectric film GDFS includes a dielectric film DFS1 and the ferroelectric film FFS1. The dielectric film DFS1 is formed on the semiconductor substrate SS, and the ferroelectric film FFS1 is formed on the dielectric film DFS1 so that the dielectric film DFS1 is disposed between the semiconductor substrate SS and the ferroelectric film FFS1. The dielectric film DFS1 is formed of a paraelectric film, and is formed of, for example, a silicon oxide film. In a direction perpendicular to the upper surface of the semiconductor substrate SS, the thickness of the dielectric film DFS1 is, for example, 1 nm or more and 3 nm or less. The dielectric film DFS1 has a function of preventing electrons from entering the ferroelectric film FFS1 from the semiconductor substrate SS when the voltage is applied to the gate electrode GES. If electrons can be prevented from entering the ferroelectric film FFS1 without the dielectric film DF1, or if the effect of electrons entering the ferroelectric film FFS12 does not need to be considered, the dielectric film DFS1 may not be formed. The ferroelectric film FFS1 disposed between the dielectric film DFS1 and the gate electrode GES is formed of, for example, a metal oxide film, and is formed of a high dielectric constant film having a dielectric constant higher than that of the silicon nitride film. The ferroelectric film FFS1 includes, for example, hafnium, oxygen, and zirconium. The ferroelectric film FFS1 may include at least one of silicon, germanium, yttrium, lanthanum, and ytterbium instead of zirconium. In the direction perpendicular to the upper surface of the semiconductor substrate SS, the thickness of the ferroelectric film FFS1 is, for example, 6 nm or more and 20 nm or less.

The metal film MFS1 formed on the gate dielectric film GDFS is disposed between the gate dielectric film GDFS and the gate electrode GES. The metal film MFS1 is formed of, for example, a titanium nitride film, a tantalum nitride film, or a tungsten film. In the direction perpendicular to the upper surface of the semiconductor substrate SS, the thickness of the metal film MFS1 is, for example, 2 nm or more and 20 nm or less. The metal film MFS1 is used to efficiently crystallize the ferroelectric film FFS1. Therefore, the metal film MFS1 may not be formed as long as the ferroelectric film FFS1 can be efficiently crystallized without forming the metal film MFS1. The metal film MFS1 and the gate electrode GES function as the gate electrode of the MISFET.

The gate electrode GES is formed on the gate dielectric film GDFS. Specifically, when the metal film MFS1 is formed on the gate dielectric film GDFS, the gate electrode GES is formed on the metal film MFS1. The gate electrode GES is formed of, for example, a polycrystalline silicon film into which an n-type impurity is introduced. The gate electrode GES may be formed of a titanium nitride film, an aluminum film, or a tungsten film. In addition, the gate electrode GES may be formed of a stacked film including two or more conductive films.

The sidewall dielectric films SDF3 are formed on the semiconductor substrate SS and the side surfaces of the gate electrode GES. The sidewall dielectric films SDF3 are formed of, for example, a stacked film including a silicon oxide film and a silicon nitride film.

The interlayer dielectric film IDF is formed on the semiconductor substrate SS so as to cover the ferroelectric memory cell and the MISFET. The contact plugs include a contact plug CP3 and a contact plug CP4 in addition to the contact plug CP1 and the contact plug CP2. The contact plug CP3 is disposed on the drain region DR2, and the contact plug CP4 is disposed on the source region SR2. Although not shown, the semiconductor device includes a contact plug disposed on the gate electrode GES.

### Manufacturing Method of Semiconductor Device

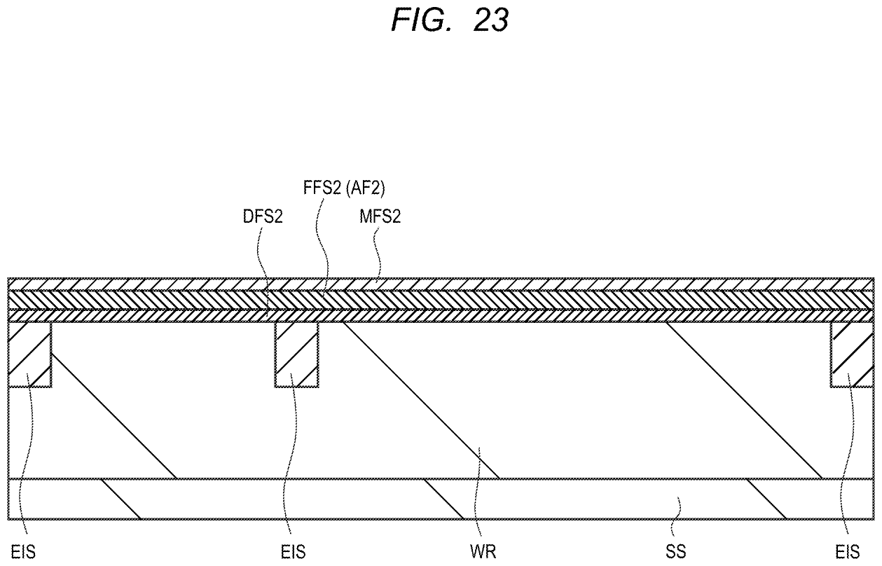

As shown in FIG. 23, a heat treatment is performed on the upper surface of the semiconductor substrate SS to form the dielectric film DFS2 on the semiconductor substrate SS. The dielectric film DFS2 is formed at a portion of the semiconductor substrate SS where the ferroelectric memory cell is to be formed and at a portion of the semiconductor substrate SS where the MISFET is to be formed. The heat treatment for forming the dielectric film DFS2 is performed in an oxygen-containing atmosphere. In the direction perpendicular to the upper surface of the semiconductor substrate SS, the thickness of the dielectric film DFS2 is, for example, 1 nm or more and 3 nm or less. Next, an amorphous film AF2 is formed on the dielectric film DFS2 by, for example, an ALD method. The amorphous film AF2 is formed at the portion of the semiconductor substrate SS where the ferroelectric memory cell is to be formed and at the portion of the semiconductor substrate SS where the MISFET is to be formed. In the direction perpendicular to the upper surface of the semiconductor substrate SS, the thickness of the amorphous film AF2 is, for example, 6 nm or more and 20 nm. The amorphous film AF2 includes, for example, hafnium, oxygen, and zirconium. The amorphous film AF2 may include at least one of silicon, germanium, yttrium, lanthanum, and ytterbium instead of zirconium.

Next, a metal film MFS2 is formed on the amorphous film AF2 by, for example, a CVD method or a sputtering method. The metal film MFS2 is formed at the portion of the semiconductor substrate SS where the ferroelectric memory cell is to be formed and at the portion of the semiconductor substrate SS where the MISFET is to be formed. The metal film MFS2 is formed of, for example, titanium nitride, tantalum nitride, or tungsten. In the direction perpendicular to the upper surface of the semiconductor substrate SS, the thickness of the metal film MFS2 is, for example, 2 nm or more and 20 nm or less. The metal film MFS2 is formed to apply stresses to the amorphous film AF2. Next, a heat treatment is performed on the amorphous film AF2 to crystallize the amorphous film AF2, thereby forming the ferroelectric film FFS2. The method of crystallizing the amorphous film AF2 is the same as the method of crystallizing the amorphous film AF1 in the first embodiment.

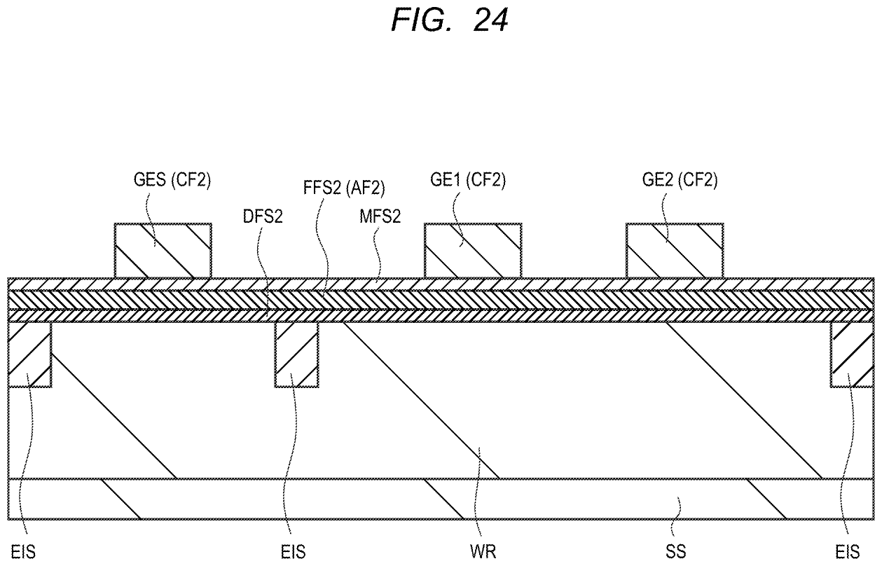

Next, as shown in FIG. 24, a conductive film CF2 is formed on the metal film MFS2 by, for example, a CVD method. The conductive film CF2 is formed of, for example, polycrystalline silicon into which an n-type impurity is introduced. When the metal film MFS2 is not formed on the ferroelectric film FFS2, the conductive film CF2 is formed on the ferroelectric film FFS2. Next, the conductive film CF2 is processed by anisotropic etching to form the gate electrode GE1, the gate electrode GE2, and the gate electrode GES.

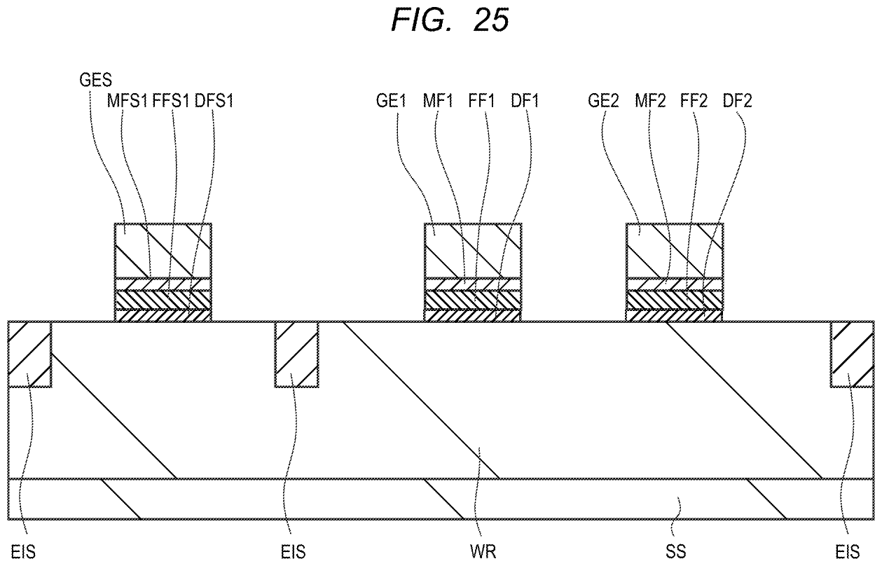

Next, as shown in FIG. 25, the metal film MFS2, the ferroelectric film FFS2, and the dielectric film DFS2 are processed by an anisotropic etching method using the gate electrode GE1, the gate electrode GE2, and the gate electrode GES as masks. Thus, the metal film MF1, the metal film MF2, the metal film MFS1, the ferroelectric film FF1, the ferroelectric film FF2, the ferroelectric film FFS1, the dielectric film DF1, the dielectric film DF2, and the dielectric film DFS1 are formed.

Next, the drain region DR1, the drain region DR2, the source region SR1, the source region SR2, the impurity region IR, the sidewall dielectric films SDF1, the sidewall dielectric films SDF2, the sidewall dielectric films SDF3, the interlayer dielectric film IDF, and the contact plugs are formed by known methods. Thus, the semiconductor device having the structure shown in FIG. 22 is formed.

### Main Features and Effects of Second Embodiment

Various types of semiconducting elements are formed on the semiconductor substrate SS. For example, the semiconductor elements include a ferroelectric memory cell, a low withstand voltage MISFET, and a high withstand voltage MISFET. The ferroelectric memory cell, the low withstand voltage MISFET, and the high withstand voltage MISFET have different operating voltages and functions. Therefore, the structures of the gate dielectric films of the ferroelectric memory cell, the low withstand voltage MISFET, and the high withstand voltage MISFET differ from each other. For example, the gate dielectric film of the low withstand voltage MISFET and the gate dielectric film of the high withstand voltage MISFET are formed of silicon oxide. In the direction perpendicular to the upper surface of the semiconductor substrate SS, the thickness of the gate dielectric film of the high withstand voltage MISFET is greater than the thickness of the gate dielectric film of the low withstand voltage MISFET.

Referring back to FIG. 17, in the ferroelectric memory cell according to the comparative example, the structure of the gate dielectric film GDFC1 of the select transistor differs from the structure of the gate dielectric film GDFC2 of the memory transistor. Therefore, referring back to FIG. 10 to FIG. 13, the dielectric film DFC, the ferroelectric film FFC1, and the metal film MFC1 need to be processed so that the dielectric film DFC, the ferroelectric film FFC1, and the metal film MFC1 are formed at desired positions. Therefore, the number of manufacturing steps increases in the comparative example. Similarly, the structure of the gate dielectric film of the MISFET differs from the structure of the gate dielectric film GDFC1 of the select transistor and the structure of the gate dielectric film GDFC2 of the memory transistor. Therefore, a step of processing the gate dielectric film of the MISFET is performed so that the gate dielectric film of the MISFET is formed at a desired position. Therefore, the number of manufacturing steps increases.

In the second embodiment, as shown in FIG. 22, the gate dielectric film GDF1 includes the ferroelectric film FF1, the gate dielectric film GDF2 includes the ferroelectric film FF2, and the gate dielectric film GDFS includes the ferroelectric film FFS1. Then, as shown in FIG. 25, the ferroelectric film FF1, the ferroelectric film FF2, and the ferroelectric film FFS1 are formed by processing the ferroelectric film FFS2.

As shown in FIG. 25, the metal film MFS2, the ferroelectric film FFS2, and the dielectric film DFS2 are processed using the gate electrode GE1, the gate electrode GE2, and the gate electrode GES as masks to form the gate dielectric film GDF1, the gate dielectric film GDF2, and the gate dielectric film GDFS. In the second embodiment, the mask film MKC1, the mask film MKC2, and the mask film MKC3 do not need to be formed, and the mask film for processing the gate dielectric film GDFS does not need to be formed. In the second embodiment, since the step of processing the gate dielectric film GDFS does not need to be performed, the number of manufacturing steps can be reduced, and the manufacturing step can be simplified. Compared with the semiconductor device according to the comparative example, the semiconductor device according to the second embodiment can be miniaturized similar to the first embodiment.

The techniques described in the first modified example of the first embodiment are applicable to the techniques described in the second embodiment. That is, in the structure shown in FIG. 22, the thickness of the dielectric film DF1 may be greater than the thickness of the dielectric film DF2. In order to optimize the performance of the MISFET, the thickness of the dielectric film DFS1 may be different from the thickness of the dielectric film DF1 and the thickness of the dielectric film DF2.

Although the invention made by the inventor of the present application has been specifically described based on the embodiments, the present invention is not limited to the above-described embodiments, and various modifications can be made without departing from the gist thereof.

What is claimed is:

1. A semiconductor device comprising:
a semiconductor substrate; and
a ferroelectric memory cell formed on the semiconductor substrate,
wherein the ferroelectric memory cell comprises:
a first gate dielectric film formed on the semiconductor substrate;
a first gate electrode formed on the first gate dielectric film;
a second gate dielectric film formed on the semiconductor substrate;
a second gate electrode formed on the second gate dielectric film;
a source region formed in the semiconductor substrate; and
a drain region formed in the semiconductor substrate,
wherein the first gate dielectric film includes a first ferroelectric film, and
wherein the second gate dielectric film includes a second ferroelectric film.

2. The semiconductor device according to claim 1,
wherein the semiconductor substrate has an upper surface,
wherein the first gate dielectric film includes a first dielectric film disposed between the semiconductor substrate and the first ferroelectric film, and
wherein the second gate dielectric film includes a second dielectric film disposed between the semiconductor substrate and the second ferroelectric film.

3. The semiconductor device according to claim 2,
wherein a thickness of the first dielectric film is greater than a thickness of the second dielectric film in a direction perpendicular to the upper surface of the semiconductor substrate.

4. The semiconductor device according to claim 1,
wherein the semiconductor substrate has an upper surface, and
wherein a thickness of the first ferroelectric film is equal to a thickness of the second ferroelectric film in a direction perpendicular to the upper surface of the semiconductor substrate.

5. The semiconductor device according to claim 2,
wherein the first dielectric film is formed of a silicon oxide film, and
wherein the second dielectric film is formed of a silicon oxide film.

6. The semiconductor device according to claim 1,
wherein the first ferroelectric film includes hafnium and oxygen, and
wherein the second ferroelectric film includes hafnium and oxygen.

7. The semiconductor device according to claim 1, comprising:
an impurity region formed in the semiconductor substrate,
wherein the impurity region is disposed between the source region and the drain region.

8. The semiconductor device according to claim 7,
wherein the first gate dielectric film is formed on a portion of the semiconductor substrate located between the drain region and the impurity region, and
wherein the second gate dielectric film is formed on a portion of the semiconductor substrate located between the source region and the impurity region.

9. The semiconductor device according to claim 1,
wherein the ferroelectric memory cell comprises:
a first metal film disposed between the first ferroelectric film and the first gate electrode; and
a second metal film disposed between the second ferroelectric film and the second gate electrode.

10. The semiconductor device according to claim 1, comprising:
an interlayer dielectric film formed on the semiconductor substrate so as to cover the ferroelectric memory cell;
a first contact plug formed in the interlayer dielectric film and connected to the drain region; and
a second contact plug formed in the interlayer dielectric film and connected to the source region.

11. A method of manufacturing a semiconductor device, the method comprising:
(a) preparing a semiconductor substrate;
(b) forming a third ferroelectric film on the semiconductor substrate;
(c) forming a conductive film on the third ferroelectric film;
(d) processing the conductive film to form a first gate electrode and to form a second gate electrode;
(e) after the (d), processing the third ferroelectric film to form a first ferroelectric film between the first gate electrode and the semiconductor substrate and to form a second ferroelectric film between the second gate electrode and the semiconductor substrate; and
(f) forming a source region and a drain region in the semiconductor substrate,
wherein the first gate electrode, the second gate electrode, the first ferroelectric film, the second ferroelectric film, the source region and the drain region configure a ferroelectric memory cell.

12. The method according to claim 11, comprising:
(g1) before the (b), forming a third dielectric film on the semiconductor substrate,
wherein in the (b), the third ferroelectric film is formed on the third dielectric film, and
wherein in the (e), the third dielectric film is processed to form a first dielectric film between the semiconductor substrate and the first ferroelectric film and to form a second dielectric film between the semiconductor substrate and the second ferroelectric film.

13. The method according to claim 11, comprising:
(g1) before the (b), forming a third dielectric film on the semiconductor substrate;
(g2) after the (g1) and before the (b), removing a portion of the third dielectric film; and
(g3) after the (g2) and before the (b), forming a fourth dielectric film on the semiconductor substrate,
wherein in the (b), the third ferroelectric film is formed on the third dielectric film and the fourth dielectric film,
wherein in the (e), the third dielectric film and the fourth dielectric film are processed to form the first dielectric film between the semiconductor substrate and the first ferroelectric film and to form the second dielectric film between the semiconductor substrate and the second ferroelectric film, and
wherein a thickness of the first dielectric film is greater than a thickness of the second dielectric film in a direction perpendicular to an upper surface of the semiconductor substrate.

14. The method according to claim 12,
wherein the first dielectric film is formed of a silicon oxide film, and
wherein the second dielectric film is formed of a silicon oxide film.

15. The method according to claim 11,
wherein the first ferroelectric film includes hafnium and oxygen, and
wherein the second ferroelectric film includes hafnium and oxygen.

16. The method according to claim 11,
wherein in the (f), an impurity region is formed in the semiconductor substrate,
wherein the impurity region is disposed between the source region and the drain region.

17. The method according to claim 16,
wherein the first ferroelectric film is formed on a portion of the semiconductor substrate located between the drain region and the impurity region, and
wherein the second ferroelectric film is formed on a portion of the semiconductor substrate located between the source region and the impurity region.

18. The method according to claim 11, comprising:
(h) after the (b) and before the (c), forming a third metal film on the third ferroelectric film,
wherein in the (e), the third metal film is processed to form a first metal film between the first gate electrode and the first ferroelectric film and to form a second metal film between the second gate electrode and the second ferroelectric film.
